(19) United States
(12) Patent Application Publication
(10) Pub. No.: US 2018/0269824 A1
(43) Pub. Date: Sep. 20, 2018

(54) SOLAR TILES WITH OBSCURED PHOTOVOLTAICS

(71) Applicant: Tesla, Inc., Palo Alto, CA (US)

(72) Inventors: Alex Christopher Mayer, Mill Valley, CA (US); Christos Gougoussis, Cupertino, CA (US)

(73) Assignee: Tesla, Inc., Palo Alto, CA (US)

(21) Appl. No.: 15/924,842

(22) Filed: Mar. 19, 2018

Related U.S. Application Data
(60) Provisional application No. 62/473,977, filed on Mar. 20, 2017.

(51) Int. Cl. H02S 20/25; H01L 31/049; H01L 31/048; E04D 1/28; E04D 1/30; C03C 17/22; C03C 17/30

(52) U.S. Cl. CPC H02S 20/25; H01L 31/049; H01L 31/0481; E04D 2001/308; E04D 1/30; C03C 17/22; C03C 17/30; E04D 1/28

(57) ABSTRACT

A solar tile having an obscured photovoltaic layer is described. The solar tile includes a back-sheet layer. The solar tile includes a bottom encapsulant layer adjacent to the back-sheet layer. One or more photovoltaic cells is provided adjacent to the bottom encapsulant layer. The solar tile includes a louver layer having porous louvers. A top encapsulant layer is provided adjacent to the one or more photovoltaic cells. The top encapsulant layer has a plurality of louvers constructed therein to block side view of the one or more photovoltaic cells. The solar tile further includes a top layer adjacent to the top encapsulant layer.

### CROSS-REFERENCE TO RELATED APPLICATION

The present U.S. Utility Patent Application claims priority pursuant to 35 U.S.C. § 119(e) to U.S. Provisional Application No. 62/473,977, entitled “SOLAR TILES WITH OBSCURED PHOTOVOLTAICS”, filed Mar. 20, 2017, which is hereby incorporated herein by reference in its entirety and made part of the present U.S. Utility Patent Application for all purposes.

### BACKGROUND

### Technical Field

The present invention relates to photovoltaic systems and more particularly to obscuring the photovoltaic portion within a solar tile and/or building integrated photovoltaic (BIPV) roof tiles, shingles, etc. from view along certain site lines or vantage points using a film that comprises louvers with a porous structure.

### Description of Related Art

Photovoltaics (“PVs”) are being incorporated into current roofing materials, such as shingles, tiles, slate, and other roofing material to form so-called solar roofs. These solar roofs are designed to function just like traditional roofing materials but also produce solar electricity from the photovoltaic components. Because the solar roof is intended to look aesthetically pleasing, it is desirable to obscure the photovoltaics from view along certain site lines while allowing as much incident sunlight to impinge on the photovoltaic as possible.

### SUMMARY

The present disclosure describes constructional features of a solar tile having an obscured photovoltaic layer for enhanced aesthetics. The solar tile includes a back-sheet layer and a bottom encapsulant layer adjacent to the back-sheet layer. One or more photovoltaic cells is provided adjacent to the bottom encapsulant layer. The solar tile includes a louver layer having porous louvers. A top encapsulant layer is provided adjacent to the plurality of photovoltaic cells. The top encapsulant layer includes a plurality of louvers to partially obscure the one or more photovoltaic cells. The solar tile further includes a top layer adjacent to the top encapsulant layer. The present disclosure further describes a method of synthesizing the solar tile with constructional features as described above.

### BRIEF DESCRIPTION OF THE SEVERAL VIEWS OF THE DRAWINGS

FIG. 1 is a diagram illustrating the relationship between a solar roof mounted on an angled roof of a dwelling, a pedestrian observer, and the sun.

FIG. 2A is a sectional side view illustrating a laminated solar tile constructed according to one or more embodiments of the present invention.

FIG. 2B is a top view illustrating the photovoltaic stackup and surrounding traditional roofing material according to one or more embodiments of the present invention.

FIG. 3 is a diagram illustrating the louver layer constructed according to one or more embodiments of the present invention.

FIG. 4A is a graph that illustrates the percent transmission for two different orientations of incident light according to one or more aspects of the present invention.

FIG. 4B is a diagram illustrating the shadow area that results from louvers within the louver layer according to one or more aspects of the present invention.

FIG. 5 is a graph that illustrates the critical angle as a function of the difference in index of refraction between two materials according to one or more aspects of the present invention.

FIG. 6 is a graph illustrating the difference in refractive index of a material and the material with differing porosity levels according to one or more aspects of the present invention.

FIGS. 7A-7G show steps to produce a louver layer with porous louvers according to one or more aspects of the present invention.

FIG. 8 is a diagram of a louver layer produced according to one or more aspects of the present invention.

FIG. 9 is a diagram illustrating the chemical structure of TEOS according to one or more aspects of the present invention.

### DETAILED DESCRIPTION OF THE DISCLOSURE

Here, we provide a description of a solar roof that has one or more louvered films to help obscure photovoltaics, particularly those incorporated as part of a solar roof.

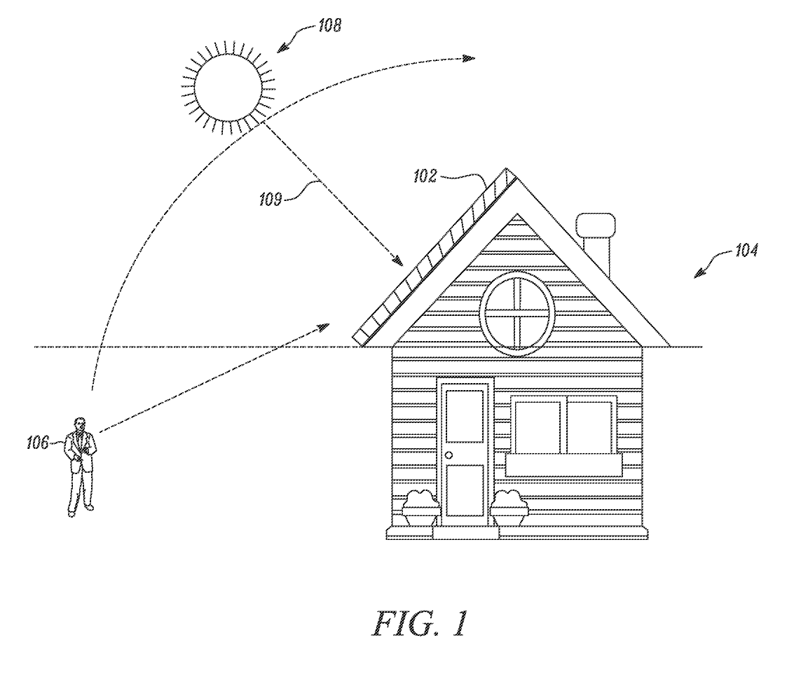

FIG. 1 is a diagram illustrating the relationship between a solar panel 102 (or solar panel array) mounted on an angled roof of a dwelling 104, a pedestrian observer 106, and the sun 108. As illustrated and generally known, it is desired to have the solar panel 102 perpendicular to the angle of incidence of the solar rays 109 coming from the sun 108 to maximize captured solar energy and convert the captured solar energy to electrical energy. The pedestrian observer 106 of the solar panel 102 may judge the solar panel 102 unsightly. Further, the view of the solar panel 102 may violate restrictive covenants or detract from the aesthetic qualities of the home or other structure upon which the solar panel 102 mounts. Thus, according to some embodiments, the solar panel 102 has a construct that helps to obscure the solar panel 102 from being viewed by the pedestrian observer 106. In the construct of the solar panel 102, the solar panel 102 includes one or more louver layers. The structure of such a solar panel will be described further with reference to the other figures. The louver layer of the solar panel 102 causes the solar panel 102 to have a substantially or fully solid color when viewed at a side angle, such as the side angle of the pedestrian observer 106. That is, the louver layer helps to obscure the solar panel 102 or a solar cell from view along certain sight lines. The louver layer optionally includes a film that contains the louvers.

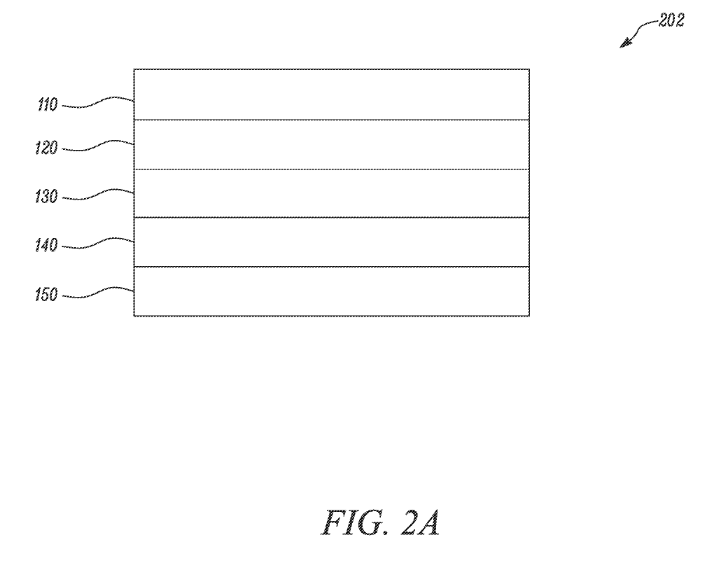

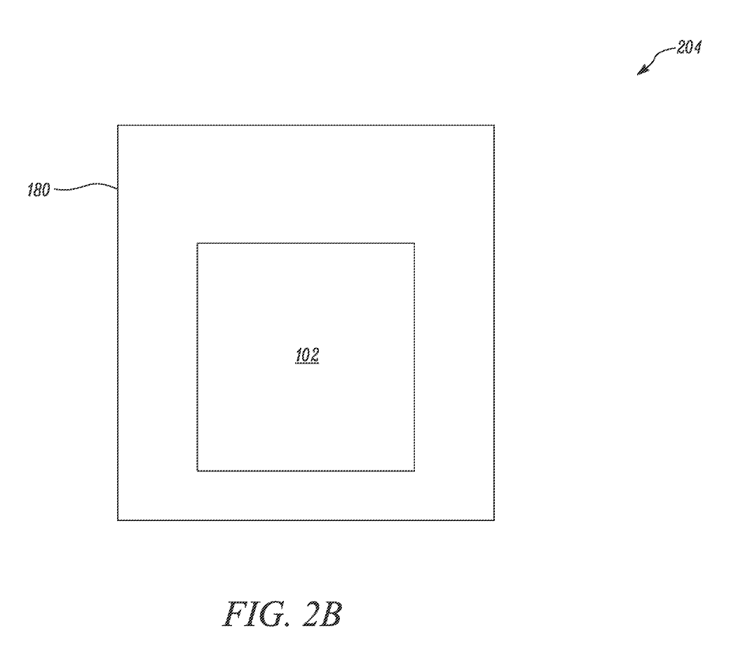

FIG. 2A shows an exemplary photovoltaic stackup 202 within a solar tile 204. Top encapsulant layer 120 and bottom encapsulant layer 150 sandwich photovoltaic 140 and louver layer 130. A top layer that is a glass layer 110 is above top encapsulant layer 120. In certain embodiments, the louver layer 130 may be colored using a pigment, such as nano-sized particles of iron oxide (Fe₂O₃), cobalt oxide, chromium oxide, copper oxide, manganese oxide, nickel oxide, titanium oxide, or any other such pigment. The present disclosure is not limited by choice of any such pigment in any manner. In certain embodiments, the louver layer 130 may be disposed above top encapsulant layer 120 and/or glass layer 110. The exact position of the louver layer 130 may be chosen to minimize the reflection from one layer to the next, which depends on the difference in index of refraction between the different layers, in order to maximize the amount of sunlight that impinges upon the photovoltaic 140. Other embodiments of the solar-tile photovoltaic stackup 202 may omit one or more layers or include additional layers, as long as photovoltaic 140 and louver layer 130 are present. Further, traditional roofing materials may be disposed around the photovoltaic stackup 202. That is the photovoltaic stackup 202 shown in FIG. 2A may only occupy a portion of the solar tile 204 as shown in FIG. 2B.

FIG. 2B illustrates the photovoltaic stackup 202 surrounded by traditional roofing material 180. The traditional roofing material 180 is intended to mean roofing materials that do not contain photovoltaics. For example, traditional roofing material 180 may be asphalt shingle, glass, slate, terracotta, another traditional roofing material, a roofing material intended to mimic the aesthetics of a traditional roofing material, or any other roofing material.

In certain embodiments, the top encapsulant layer 120 and the bottom encapsulant layer 150 are constructed of ethylene-vinyl acetate (EVA), also known as poly(ethylene-vinyl acetate) (PEVA), which is the copolymer of ethylene and vinyl acetate. In other embodiments, another polymer or polymer blend may be used. The photovoltaic layer 140 may comprise conventional photovoltaics (PVs) or shingled PVs. The glass layer 110 may be constructed of glass that is textured, toughed, having low iron content and of a thickness sufficient to protect the underlying components.

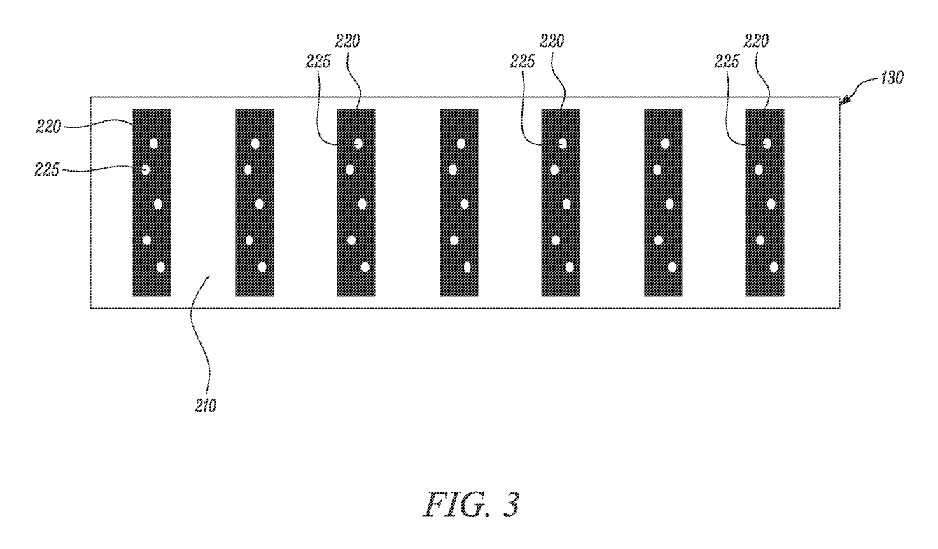

As shown in FIG. 3, louver layer 130 comprises louvers 220 with pores 225 inside the louver 220. The louver layer 130 may be a polymer sheet, polymer film, glass sheet, or other suitable layer that contains the louvers 220 with pores 225. The louver layer 130 may be dyed using a nano pigment to better match the surrounding traditional roofing material 180. For example, nano-sized particles of iron oxide (Fe₂O₃), cobalt oxide, chromium oxide, copper oxide, manganese oxide, nickel oxide, or another pigment may be used to color the louver layer 130. As shown in FIG. 3, louvers 220 are regularly spaced within the bulk material 210. The louvers 220 contain pores 225 and are preferentially spaced at regular intervals. In certain embodiments, the louvers 220 are irregularly spaced, for example, the louvers 220 may be grouped closer together at either end and more widely spaced in the center, or vice versa. The pores 225 within the louvers 220 may be formed by dispersing hollow beads or other three-dimensional structures throughout the louvers 220. In an exemplary embodiment, the pores 225 are formed by dispersing hollow silica beads within the louvers 220 that themselves comprise silica.

For example, in one embodiment, the pores 225 within the louvers 220 are formed by adding a porosity agent such as hollow silica beads into a polymer film. Compared to the bulk material 210 of the film, typically a transparent polymer, the beads have a lower refractive index (typically a value of close to 1 when the beads contain air or a vacuum). The bulk material 210 may be polyethylene, poly(ethylene terephthalate), tetraethoxysilane, or another polymer depending on the desired properties, including pliability, structural integrity, and desired index of refraction. In order to generate a specific refractive index difference between the bulk material and the louvers 220 that contain pores 225, models may be employed to approximate the level of porosity needed to generate a specific refractive index difference for a given material used in the bulk material 210 and a given material used in the louver 220. Specifically, a Maxwell-Garnett model or a Bruggeman model may be used to approximate a desired layer of porosity in the louvers 220 to produce a specific difference in refractive difference.

For example, applying a Bruggeman model to a system of a louver layer comprising vertical louvers that have pores, the Bruggeman formula takes the form:

$${\sum }_{i} {δ}_{i} \frac{{ϵ}_{i} - {ϵ}_{e}}{{ϵ}_{i} + 2 {ϵ}_{e}} = 0$$

Where δᵢ is the fraction of the component, ϵᵢ is the dielectric permittivity of each component, and ϵₑ is the effective dielectric permittivity of the medium. The dielectric permittivity is related to the refractive index as ε=n².

The resulting louver layer 130 with louvers 220 that is produced using pores 225 within a polymer matrix results in total internal reflection for light rays in which the angle of incidence is greater than the critical angle. Total internal reflection results in light coming at low incidence angle (vs normal) being reflected, giving high cell efficiency and the high incidence angle light being absorbed, giving a good hiding power for an observer on the street. FIG. 3 illustrates one or more solar photovoltaic stackups 202 on an angled roof. Light coming at a low incident angle (for example, light viewed by an observer on the street) is reflected, and the observer does not see the photovoltaic 140 in the solar stackup. Conversely, light rays that are incident on the photovoltaic stackup 202 with a low-incident angle are not reflected. Rather, they are incident onto the underlying photovoltaic 140, which in turn may generate energy in the form of an electric current.

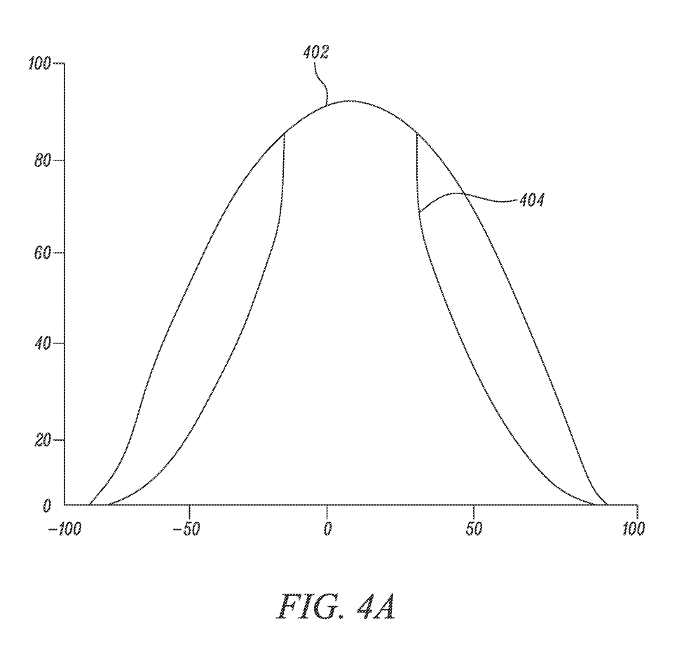

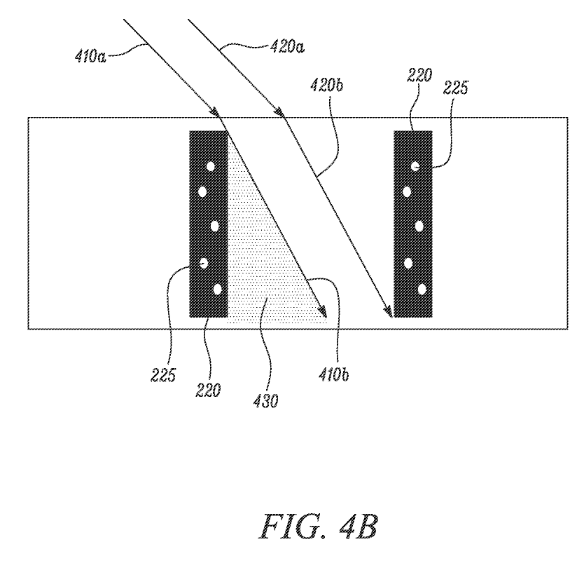

The control of the refractive index difference between the louvers 220 and the pores 225 is important to produce louver layers 130 that have the desired properties and are good for processing and reliability. When differences in refractive index are created through matching two different polymers, there are issues in reliably and reproducibly creating louver layers with the desired properties (difference in index of refraction). According to certain embodiments, this difficulty can be overcome by adding empty beads to the louver material polymer, so that the refractive index difference can be adjusted very simply. The angle of view (for hiding power) and solar cell efficiency depend on the refractive index difference, which itself depends on the porosity level, as illustrated in FIGS. 4A, 5, and 6.

FIG. 4A illustrates the transmittance of sunlight to the photovoltaic 140 for two different incident situations. Curve 402 illustrates the theoretical transmittance for light that is incident when the sun is approximately perpendicular to the photovoltaics 140 in the solar tiles 204 (curve labeled 90 degrees). Curve 404 illustrates the theoretical transmittance for light that is incident when the sun is at a low angle to the photovoltaics 140 in the solar tiles 204 (curve labeled 0 degrees).

FIG. 4B illustrates this situation when the sun is at a low angle to the photovoltaics 140 in the solar tile 204. When light rays are refracted while entering louver layer 130, the louvers 220 cause a shadow to be cast. More specifically, as illustrated in FIG. 4B, light ray 410a is incident on louver layer 130 so that the refracted light ray 410b just passes to the right of louver 220. Incident rays that hit the louver layer 130 to the left of incident ray 410a will be reflected, refracted, or attenuated in such a manner such that shadow region 430 is formed. Light rays 420a to the right of light ray 410a are refracted as light ray 420b when entering louver layer 130 such that they will pass through the louver layer 130 and be incident onto the photovoltaic 140 below (or the layer present below the louver layer 130).

As can be seen in FIG. 4A, when the sun is approximately perpendicular to the photovoltaic 140 in the solar tile 204 (corresponding to curve 402), the transmission is a smooth curve, similar in shape to an inverted parabola or a half-wavelength sine wave. Such a transmission profile is very similar to the transmission profile if no louvers 220 existed in the louver layer 130. When the sun is at lower angle, the transmission of the incident light to the photovoltaic 140 is reduced. As illustrated in FIG. 4A shadow modes on either side of the curve 404 exhibit reduced light transmission to the underlying layer or photovoltaic. Near the maximum transmission (approximately 0 degrees+/−25 degrees) in FIG. 4A, total internal reflection (TIR) occurs and a high percentage of incident light is transmitted through the louver layer 130 to the underlying photovoltaic 140 (or other layer). The exact transition between the TIR region and the rebound mode, which is closely followed by the shadow mode, occurs at a critical angle that is a function of the difference in refractive index between the bulk material 210 and the louvers 220. Similarly, a pedestrian observer 106 who also observes the solar roof and solar tiles 204 at a low angle will not observe the underlying photovoltaic 140.

Table 1 illustrates the index of refraction of different materials that may be used to form louver layer 130 according to certain embodiments of the present invention. The index of refractions for certain polymers may deviate from the values listed in Table 1. For example, molecular weight or the polymeric chain length may cause the index of refraction to deviate from the values listed in Table 1. Thus, the index of refraction may be altered or tweaked to produce the desired starting index of refraction using one of the carbon-based polymers or silicon-based polymers identified in Table 1.

TABLE 1

| Polymer | Index of Refraction |
|---|---|
| Poly(methyl hydro siloxane) | 1.397 |
| Poly(dimethyl siloxane) | 1.4035 |
| Silica | 1.46 |
| Poly(propylene oxide) | 1.457 |
| Poly(vinyl acetate) | 1.4665 |
| Poly(ethyl acrylate) | 1.4685 |
| Poly(vinyl butyral) | 1.485 |
| Poly(methyl methacrylate) | 1.4893 |
| Polypropylene, isotactic | 1.49 |
| Poly(vinyl alcohol) | 1.5 |
| Poly(isobutylene) | 1.51 |
| Polyethylene | 1.51 |
| Poly(acrylonitrile) | 1.5187 |
| Poly(isoprene), cis | 1.5191 |
| Poly(acrylic acid) | 1.527 |
| Poly(methyl phenyl siloxane) | 1.533 |
| Poly(vinyl chloride) | 1.539 |
| Polyethylene, high density | 1.54 |
| Poly(vinylfuran) | 1.55 |
| Poly(ethylene terephthalate) | 1.575 |
| Polystyrene | 1.5894 |
| Poly(styrene sulfide) | 1.6568 |

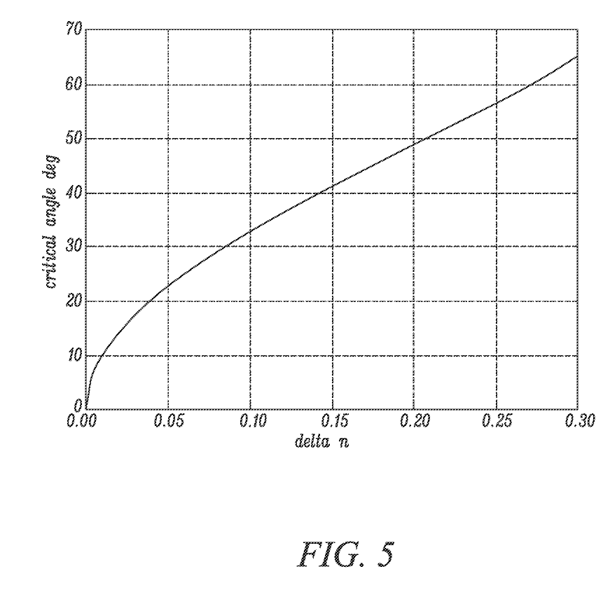

FIG. 5 illustrates the critical angle as a function of the difference in index of refraction between two different materials. Depending on the specific properties desired and the desired transmission profile, FIG. 5 can be used to help select specific materials for use or, alternatively, to help predict the critical angle once materials are selected (and their indices of refraction are known).

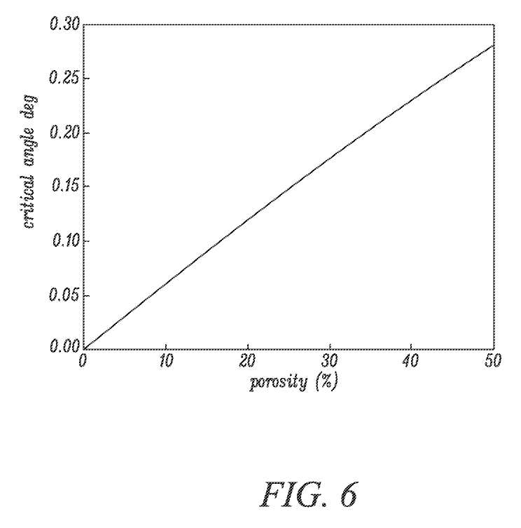

FIG. 6 illustrates the critical angle as a function of difference in index of refraction between a material with no porosity and a material with varying amounts of porosity. FIG. 6 can be used to select the desired level of porosity for the louvers 220 to produce the desired difference in refractive index. The volume percentage of pores 225 within louvers 220 provides a refractive index, which then produces a critical angle for the transition from TIR mode to rebound mode (and then to shadow mode).

As illustrated in FIGS. 5 and 6 and discussed above, by tuning the porosity of the material, we can tune the critical angle at which the louver 220 starts to have an obscuring effect. For example, when the louvers 220 have a porosity of 20% and the remaining portion of the louver 220 is made from a material with refractive index 1.55, we obtain a refractive index difference of 0.1. This refractive index difference of 0.1 corresponds to a critical angle of 33 degrees.

In certain embodiments, the louver layer 130 has a bulk material that has an index of refraction of approximately 1.55. For example, polyethylene, polyvinyl furan, or another appropriate polymer may be used. The louvers 220 may comprise a pigment and a porous agent to obtain a refractive index of 1.45. The louvers 220 may be spaced with a spacing s and with a height h such that s/h is between 0.3 and 3.0, for example s=100 microns and h=100 microns.

In another embodiment, the louver layer 130 is formed from a bulk material that is fused silica, with an index of refraction of approximately 1.46. If the louver 220 is formed from a fused silica a porosity of 20%, the difference in the index of refraction between the bulk material and the louver 220 is 0.1.

According to specific embodiments, the louver layer 130 with louvers 220 that contain pores 225 may be synthesized using a sol-gel process. A durable, low-cost louver layer may be synthesized using a sol-gel process by selecting the appropriate materials. For example, a louver layer may be synthesized by adding a porosity agent such as a polymer or polymer beads to a solution of tetraethoxysilane (TEOS), which is also known as tetraethyl orthosilicate. The chemical formula for TEOS is Si(OC₂H₅)₄, and FIG. 9 illustrates its chemical structure.

A sol-gel reaction may then be used to synthesize silica at high temperature, followed by the removal of the porous agent at high temperature to create pores in the material. Alternatively, if the pores are formed using a hollow material as the porous agent, then the porous agent may not need to be removed. The pores may be spherical, oval, or another geometry and the pores may be a fully or partially connected network, especially if the porous agent is removed through elevating the temperature. The result of the sol-gel process is a film that contains a series of louvers 220 that contain pores 225 that are typically filled only with air, although they could be filled with another polymer or gas as desired.

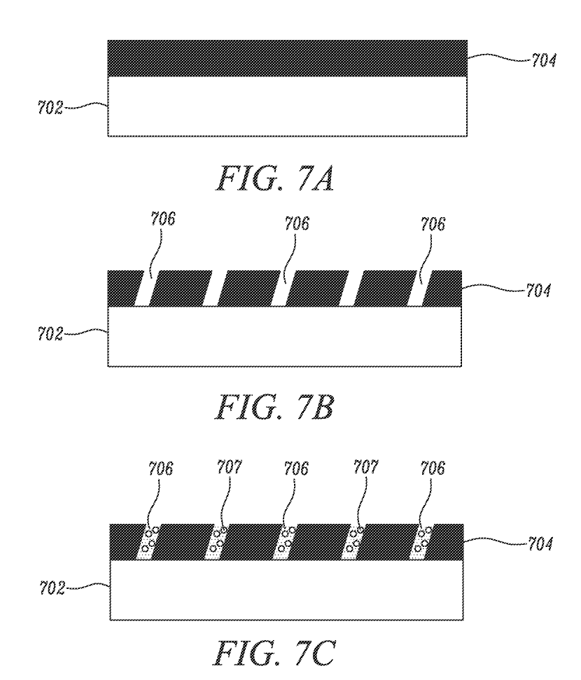

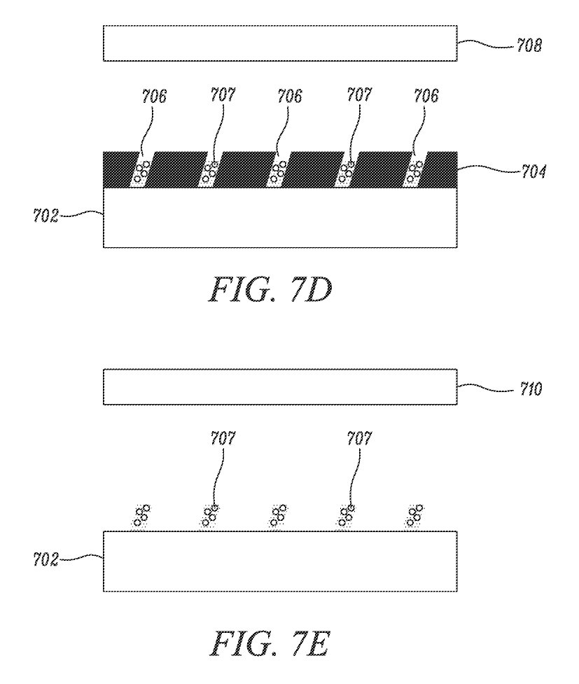

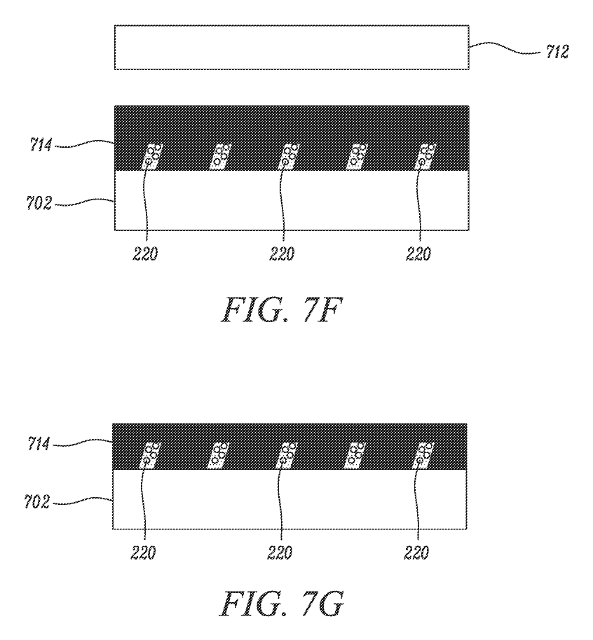

More specifically, the synthesis of the louver layer 130 on a glass substrate, according to certain embodiments, is shown in FIGS. 7A-7G. As illustrated in FIG. 7A, the process to create the louver layer 130 starts with coating a glass substrate 702 with a photoresist layer 704. Known coating techniques, like spin coating, spray coating, dip coating, roller coating, or another technique may be used. FIG. 7B shows next step, in which the photoresist layer 704 may be removed. The removal may be done using a negative resist followed by etching of the photoresist layer 704 to leave the photoresist layer 704 with vertical channels 706. FIG. 7C shows the next step. After the vertical channels 706 have been formed in the photoresist layer 704, a solution 707 of TEOS in a solvent (such as water) is coated onto the photoresist layer 704, filling (at least partially) the vertical channels 706. Again, known coating techniques, like spin coating, spray coating, dip coating, roller coating, or another technique may be used. The solution 707 contains dispersed beads and may also contain a pigment to help match the color of the louver layer 130 to the rest of the solar tile 204 (surrounding the photovoltaic stackup 202). The beads may be nanosized and may be made of plastic or hollow transparent spheres. The pigment may be a nano pigment, like a nano-sized particle of iron oxide (Fe₂O₃), cobalt oxide, chromium oxide, copper oxide, manganese oxide, nickel oxide, or another pigment. This resulting structure has the solution of TEOS in water (or another solvent) with the dispersed beads and any pigment in the louvers that were previously formed by etching the photoresist.

FIG. 7D illustrates the next step in the process. Once the TEOS solution 707 (including dispersed spheres and pigment) has been coated, it is dried, typically under ambient or elevated temperatures. A drying agent 708 is symbolically represented. The drying process typically results in a volume reduction as the solvent (for example water) is removed from the system. FIG. 7E shows next step in the process. Once the TEOS solution 707 has dried, high heat is applied to remove the photoresist layer 704 and polymerize (or further polymerize) the TEOS. A high heat supplying agent 710 is represented symbolically.

When the solvent is water, the polymerization reaction may be a simple condensation reaction in which two molecules of TEOS form a covalent bond while losing a water molecule. That is one TEOS molecule may lose a hydroxyl group and the other TEOS molecule may lose a hydrogen ion. The hydroxyl group and the hydrogen ion combine to form a water (H₂O) molecule. In other embodiments, when the solvent is acidic or basic water, different polymerization reactions and mechanisms may occur. For example, acid-catalyzed or base-catalyzed condensation or hydrolysis may occur to polymerize the TEOS.

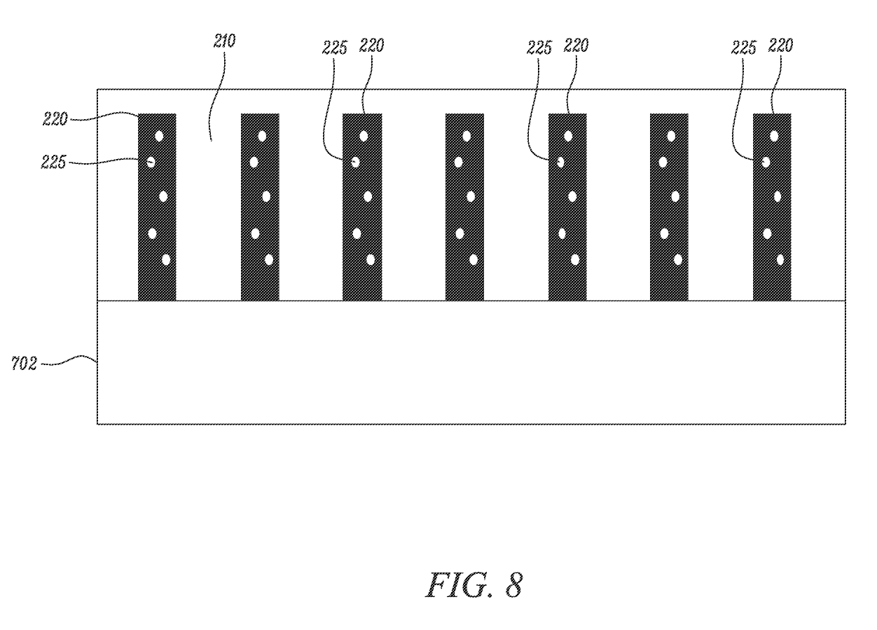

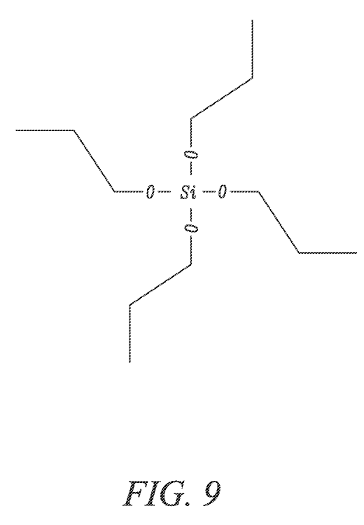

FIG. 7F illustrates the next step in the process. Once the louvers 220 have been synthesized, the bulk material 210 is coated over the louvers 220. As shown in FIG. 7E, a solution 712 of TEOS (again in water or another solvent) is coated over the formed louvers 220. Known coating techniques, like spin coating, spray coating, dip coating, roller coating, or another technique may be used. FIG. 7G illustrates the next step in the process. The TEOS solution 712 is then allowed to dry and heat applied (also known as firing) to polymerize the TEOS. A drying agent 714 is represented symbolically. When the solvent is water, the polymerization reaction may be a simple condensation reaction in which two molecules of TEOS form a covalent bond while losing a water molecule. In other words, one TEOS molecule may lose a hydroxyl group and the other TEOS molecule may lose a hydrogen ion. The hydroxyl group and the hydrogen ion combine to form a water (H₂O) molecule. In other embodiments, when the solvent is acidic or basic water, different polymerization reactions and mechanisms may occur. For example, acid-catalyzed or base-catalyzed condensation or hydrolysis may occur to polymerize the TEOS. FIG. 8 illustrates the louver layer 130 formed after all the steps described in FIGS. 7A-7G.

Different reaction conditions may produce different polymerized TEOS networks. For example, using an acid-catalyzed hydrolysis reaction with a low water to silicon ratio typically produces a weakly-branched polymerized network. Conversely, using a base-catalyzed hydrolysis reaction with a high water to silicon ratio typically produces a highly-branched polymerized network. Varying the ratio of the water to silicon (one TEOS molecule has one silicon atom) and the polymerization method can produce polymerized networks with varying amounts of cross linking. Further, in other embodiments, other chemistries and/or materials may be used to form the louver layer with porous louvers.

In the foregoing specification, the disclosure has been described with reference to specific embodiments. However, as one skilled in the art will appreciate, various embodiments disclosed herein can be modified or otherwise implemented in various other ways without departing from the spirit and scope of the disclosure. Accordingly, this description is to be considered as illustrative and is for the purpose of teaching those skilled in the art the manner of making and using various embodiments of the disclosed system, method, and computer program product. It is to be understood that the forms of disclosure herein shown and described are to be taken as representative embodiments. Equivalent elements, materials, processes or steps may be substituted for those representatively illustrated and described herein. Moreover, certain features of the disclosure may be utilized independently of the use of other features, all as would be apparent to one skilled in the art after having the benefit of this description of the disclosure.

Although the steps, operations, or computations may be presented in a specific order, this order may be changed in different embodiments. In some embodiments, to the extent multiple steps are shown as sequential in this specification, some combination of such steps in alternative embodiments may be performed at the same time. The sequence of operations described herein can be interrupted, suspended, reversed, or otherwise controlled by another process.

It will also be appreciated that one or more of the elements depicted in the drawings/figures can also be implemented in a more separated or integrated manner, or even removed or rendered as inoperable in certain cases, as is useful in accordance with a particular application. Additionally, any signal arrows in the drawings/figures should be considered only as exemplary, and not limiting, unless otherwise specifically noted.

What is claimed is:

1. A solar tile comprising:
a back-sheet layer;
a bottom encapsulant layer adjacent the back-sheet layer;
a one or more photovoltaic cells adjacent the bottom encapsulant layer;
a louver layer wherein the louver layer comprises porous louvers;
a top encapsulant layer adjacent the one or more photovoltaic cells having a plurality of louvers constructed therein to block side view of the one or more photovoltaic cells; and
a top layer adjacent the top encapsulant layer.

2. The solar tile of claim 1, wherein the louver layer comprises a carbon-based polymer.

3. The solar tile of claim 2, wherein the louvers comprise a carbon-based polymer.

4. The solar tile of claim 1, wherein the louver layer comprises a silicon-based polymer.

5. The solar tile of claim 4, wherein the louvers comprise a silicon-based polymer.

6. The solar tile of claim 5, wherein:
the louver layer further comprises a pigment of iron oxide; and
the solar tile has a differing color when viewed from other than a side angle.

7. A method of synthesizing a solar tile, the method comprising:
providing a glass substrate;
coating the glass substrate with a photoresist layer;
partially removing the photoresist layer to form vertical channels in remaining photoresist layer;
coating the remaining photoresist layer with a solution of tetraethyl orthosilicate such that the solution fills up the vertical channels;
applying heat to dry the solution;
applying heat to remove the remaining photoresist layer such that a louver layer having a plurality of louvers are formed over the glass substrate;
coating the louver layer with a layer of a bulk material; and
applying heat to dry the louver layer.

8. The method of claim 7, wherein the solution of tetraethyl orthosilicate further includes dispersed beads.

9. The method of claim 7, wherein the bulk material is a solution of tetraethyl orthosilicate.

10. The method of claim 7, wherein the louver layer comprises a carbon-based polymer.

11. The method of claim 10, wherein the louvers comprise a carbon-based polymer.

12. The method of claim 7, wherein the louver layer comprises a silicon-based polymer.

13. The method of claim 12, wherein the louvers comprise a silicon-based polymer.
